(19) United States
(12) Patent Application Publication
(10) Pub. No.: US 2001/0052604 A1
(43) Pub. Date: Dec. 20, 2001

(54) Image sensor with photo diodes

(76) Inventor: Petrus Gijsbertus Maria Centen, Breda (NL)

Correspondence Address: U. S. Philips Corporation, 580 White Plains Road, Tarrytown, NY, 10591, US

(21) Appl. No.: 09/817,976

(22) Filed: Mar. 27, 2001

(30) Foreign Application Priority Data
Apr. 3, 2000 (EP) 00201195.5

(51) Int. Cl. H01L 29/76

(52) U.S. Cl. 257/214

(57) ABSTRACT

Image sensors are known in the art and are for example used in cameras to collect the image.

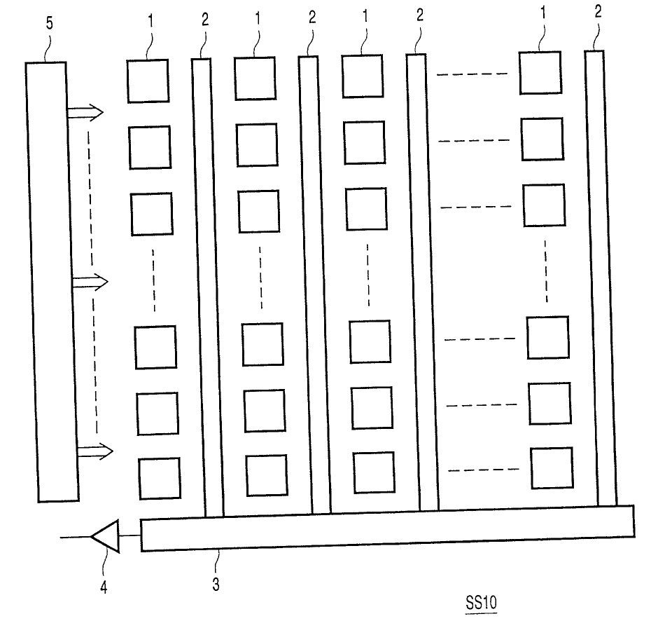

Photo-electrical conversion elements are used as charge packages in this application.

Further means are provided for selectable operating said device as an M-phase charge coupled device (M photo-electrical conversion elements), or as an N-phase charge coupled device (N photo-electrical conversion elements), N being smaller than M, for adjusting the number of image lines of the imaging device and keeping the width and the height the same and therefore the image diagonal the same.

As described in the preamble of claim 1. The invention further relates to a camera comprising such an image sensor.

Such a device is known, for example, from the published European Patent Application EP-A 0 547 697 (PHN 13.926). A charge coupled imaging device is described therein whose ratio between the width and the height (aspect ratio) is variable, in particular adjustable between two standard values, i.e. 16/9 and 4/3. The value 4/3 corresponds to the hitherto usual aspect ratio of TV pictures. The value 16/9 corresponds to the aspect ratio of wide-screen TV. For recording purposes, it offers considerable advantages to use a camera, which can be set for either of these standard values.

The cited European Patent Application EP-A 0 547 697 accordingly proposes to use an imaging device in the 16/9 version and to use all columns thereof in wide-screen applications. For applications in the 4/3 standard, on the other hand, the columns in two bands situated at the left and right edges of the matrix are not used for active video information. The signals in these columns are, for example, discharged through the read-out register in the line retrace period.

A disadvantage of this is that the number of pixels per line changes, which means that the camera frequency changes, given an equal line time, which again leads to disadvantages for the signal processing. In addition, this conversion leads to a loss in horizontal resolution and a change in the horizontal viewing angle. Generally speaking, a convertible imaging device of this known type is optimized for the 16/9 aspect ratio, but shows a less satisfactory operation in the 4/3 mode.

From the United Stated U.S. Pat. No. 4,734,772 a solid state imaging device is known using photo-electrical conversion elements.

The invention has for its object inter alia to provide such a charge coupled imaging device which can be operated both in the 1080P and/or 720P and/or 480I and/or 1080I and/or 480P, so that image width and image height are the same. The invention in addition envisages to provide a charge coupled device in which the number of lines is adjustable.

A charge coupled imaging device according to the invention is characterized in that means are provided for selectable operating said device as an M-phase charge coupled device, in which a charge package corresponds to M photo-electrical conversion elements, or as an N-phase charge coupled device, in which a charge package corresponds to N photo-electrical conversion elements, N being smaller than M, for adjusting the number of image lines of the imaging device and keeping the width and the height the same and therefore the image diagonal the same.

The change in the number of phases also changes the height of the pixels. As a result, the number of image lines can be varied through the choice of the phase for a given number of photo diodes.

By switching to a lower number of phases, whereby the number of image lines is increased and exactly fitting the number required by the ATSC standard, and having the same height and width and as a consequence the same diagonal.

It is to be noticed here that with the image sensor of the invention it is possible to either use the number M, or the number N, or both or with for example three different numbers N, M, and K.

It is to be noticed here that from the United State Patent U.S. Pat. No. 5,784,103 (PHN14744) a charge coupled imaging device of the so called FT type is known. The text if this patent is incorporated herein by reference.

An important preferred embodiment of an imaging device according to the invention is characterized in that M and N are equal to four and three, respectively. It is surprisingly found in this version that all the number of lines required by the ATSC standard at a the given aspect ratio of 16:9 becomes possible.

The embodiment which renders it possible to operate the charge coupled device as a 4-phase and as a 3-phase system without complicated circuits and/or wiring is characterized in that the electrodes are interconnected so as to form a 12-phase charge coupled device.

Further embodiments are described in the other dependent claims.

The invention and additional features, which may be optimally used to implement the invention to advantage will be apparent from and elucidated with reference to the examples described below, hereinafter and shown in the Figure. Herein shows:

The Figure schematically an example of an imaging device according to the invention.

The Figure shows schematically an example of a solid-state imaging device SSID comprising photo-electrical conversion elements 1 arranged in a matrix for accumulating signal charges corresponding to incident light, transfer gates (not shown) for reading out the signal charges accumulated in the photo-electrical conversion elements 1 every vertical scanning period (field or frame), vertical registers 2 for transferring, in the vertical direction, the read out signal accumulated during every horizontal scanning period (1H), a horizontal register 3 electrically connected to one end of the vertical registers 2 for transferring the signal charges in the horizontal direction, and an output circuit 4 for converting the signal charge transferred from the horizontal register 3 to electric signals.

A charge coupled imaging device according to the invention comprises means 5 by which the device SSID can be operated as desired, at least during charge transport, for example as an M-phase charge coupled device, in which a charge package corresponds to M photo diodes, or as an N-phase charge coupled device, in which a charge package corresponds to N photo diodes, N being smaller than M. The change in the number of phases also changes the height of the pixels. As a result, the number of image lines can be varied through the choice of the phase for a given number of photo diodes. In this way it is possible to change the size of the pixels and thus the number of lines through the phase adjustment The change in the number of phases also changes the height of the pixels. As a result, the number of image lines can be varied through the choice of the phase for a given number of photo diodes.

By switching to a lower number of phases, whereby the number of image lines is increased and exactly fitting the number required by the ATSC standard, and having the same height and width and as a consequence the same diagonal.

It is to be noticed here that with the image sensor of the invention it is possible to either use the number M, or the number N, or both or with for example three different numbers N, M, and K.

It is to be noticed here that the imaging device can also either operate as a so called FIT (Frame Interline Transfer) device or as a so called FT (Frame Transfer) device or an IT (Interline Transfer) device.

1. A charge coupled imaging device comprising a semiconductor body which is provided at a surface with a sensor matrix of image sensor elements, with a system of charge transport channels situated next to one another and extending in the semiconductor body parallel to one another and parallel to the surface, in which channels electric charge generated in the image sensor elements through absorption of radiation can be stored in the form of charge packages and transported to a read-out member under the influence of clock voltages applied to a system of clock electrodes formed above the charge transport channels, characterized in that means are provided for selectable operating said device as an M-phase charge coupled device, in which a charge package corresponds to M photo-electrical conversion elements, or as an N-phase charge coupled device, in which a charge package corresponds to N photo-electrical conversion elements, N being smaller than M, for adjusting the number of image lines of the imaging device and keeping the width and the height the same and therefore the image diagonal the same.

2. A charge coupled imaging device as claimed in claim 1, characterized in that the number of image lines of the imaging device is adjustable by selecting the number of photo diodes of which the charge is combined while the width and the height stay substantially the same.

3. A chare coupled imaging device as claimed in claim 2, characterized in that the width/height ratio in M-phase operation is or to or at least substantially equal to 4/3, and in N-phase operation is at least substantially equal to 16/9.

4. A charge coupled imaging device as claimed in claim 1, characterized in that M and N are equal to four and three, respectively.

5. A charge coupled imaging device as claimed in claim 4, characterized in that the electrodes are interconnected so as to form a 12-phase charge coupled device.

6. A charge coupled imaging device as claimed in claim 1, characterized in that the imaging device is of the frame transfer (FT) type and further comprises, a memory matrix and a read-out register coupled thereto, the charge packages being transported into the memory via the charge transport channels after an integration period and being transported line by from the memory to the read-out register through which the charge packages of one line are transported to read-out means.

7. A charge coupled imaging device as claimed in claim 6, characterized in that the memory matrix comprises more storage locations than the maximum number of charge packages for M-phase operation of the sensor matrix.

8. A charge coupled imaging device as claimed in claim 7, characterized in that the number of storage locations in the memory matrix is equal or smaller than the maximum number of charge packages formed during N-phase operation of the device.

9. A charge coupled imaging device as claimed in claim 6, characterized in that excess image lines are obtained during N-phase operation of the sensor matrix compared with the number of image lines during M-phase operation, the charge packages in two bands of image lines not being used as video information during N-phase operation, each band having a width substantially equal to half said excess images lines, a first of said two bands being situated at an edge of the sensor matrix adjoining the memory and a second of said two bands being situated at an opposite edge of the sensor matrix.

10. A charge coupled imaging device as claimed in claim 9, characterized in that, during the transfer of charge packages from the sensor matrix to the memory matrix, the first band of excess lines is transferred to the memory matrix in order to be removed through the read-out register, and the second band of excess lines is removed from the sensor matrix to a region situated below the sensor matrix and separated from the transport channels of the sensor matrix by at least a pn junction.

11. A charge coupled imaging as claimed in claim 1, characterized in that the memory matrix is formed by an M-phase charge coupled device.

12. A camera comprising a charge coupled imaging device having a semiconductor body which is provided at a surface with a sensor matrix of image sensor elements, with a system of charge transport channels situated next to one another extending in the semiconductor body parallel to one another and parallel to the surface, in which channels electric charge generated in the image sensor elements through absorption of radiation can be stored in the form of charge packages and transported to a read-out member under the influence of clock voltages applied to a system of clock electrodes formed above the charge transport channels, characterized in that means are provided for selectable operating said device as an M-phase charge coupled device, in which a charge package corresponds to M clock electrodes, or as an N-phase charge coupled device, in which a charge package corresponds to N clock electrodes, N being smaller than M, for adjusting the number of image lines while maintaining the same width and height.
